(19) United States
(12) Patent Application Publication
(10) Pub. No.: US 2014/0091392 A1
(43) Pub. Date: Apr. 3, 2014

(54) SEMICONDUCTOR DEVICE, SEMICONDUCTOR WAFER, METHOD FOR PRODUCING SEMICONDUCTOR WAFER, AND METHOD FOR PRODUCING SEMICONDUCTOR DEVICE

(71) Applicants: Sumitomo Chemical Company, Limited, Tokyo (JP); National Institute of Advanced Industrial Science And Technology, Tokyo (JP); The University of Tokyo, Tokyo (JP)

(72) Inventors: Tomoyuki TAKADA, Ichihara-shi (JP); Hisashi YAMADA, Tsukuba-shi (JP); Masahiko HATA, Tsukuba-shi (JP); Shinichi TAKAGI, Bunkyo-ku (JP); Tatsuro MAEDA, Tsukuba-shi (JP); Yuji URABE, Tsukuba-shi (JP); Tetsuji YASUDA, Tsukuba-shi (JP)

(73) Assignees: Sumitomo Chemical Company, Limited, Tokyo (JP); National Institute of Advanced Industrial Science And Technology, Tokyo (JP); The University of Tokyo, Tokyo (JP)

(21) Appl. No.: 14/099,190

(22) Filed: Dec. 6, 2013

Related U.S. Application Data
(63) Continuation-in-part of application No. PCT/JP2012/003788, filed on Jun. 11, 2012.

(30) Foreign Application Priority Data
Jun. 10, 2011 (JP) 2011-130729

(51) Int. Cl. H01L 27/092; H01L 21/8238; H01L 27/12

(52) U.S. Cl. CPC H01L 27/0922; H01L 27/1203; H01L 21/823807
USPC 257/351; 257/365; 438/458; 438/199

(57) ABSTRACT

There is provided a semiconductor device including a first channel-type first MISFET formed and a second channel-type second MISFET: a first source and a first drain of the first MISFET and a second source and a second drain of the second MISFET are made of the same conductive substance, and the work function Φ_{M} of the conductive substance satisfies at least one of relations respectively represented by (1) φ₁<Φ_{M}<φ₂+E_{g2}, and (2) |Φ_{M}−Φ₁|≦0.1 eV and |(φ₂+E_{g2})−Φ_{M}|≦0.1 eV, where φ₁ represents an electron affinity of an N-type semiconductor crystal layer, and φ₂ and E_{g2} represent an electron affinity and a band gap of a crystal of a P-type semiconductor crystal layer.

The contents of the following patent applications are incorporated herein by reference:
NO. 2011-130729 filed in Japan on Jun. 10, 2011, and
PCT/JP2012/003788 filed on Jun. 11, 2012.

### TECHNICAL FIELD

The present invention relates to a semiconductor device, a semiconductor wafer, a method for producing a semiconductor wafer, and a method for producing a semiconductor device. Note that the present application is based on the research “Technical Development on New Material for Nanoelectronics Semiconductor and New-Structure Nanoelectronic Device—Research and Development on Group III-V Semiconductor Channel Transistor Technology on Silicon Platform” of the year 2010 entrusted by the New Energy and Industrial Technology Development Organization (NEDO) and applies to Art. 19 of Industrial Technology Enhancement Act.

### BACKGROUND ART

Group III-V compound semiconductors such as GaAs and InGaAs have a high electron mobility, whereas Group IV semiconductors such as Ge and SiGe have a high hole mobility. Therefore, a high-performance CMOSFET (Complementary Metal-Oxide-Semiconductor Field-Effect Transistor) can be realized by using a Group III-V compound semiconductor is to make an N-channel-type MOSFET (Metal-Oxide-Semiconductor Field-Effect Transistor) and using a Group IV semiconductor to make a P-channel-type MOSFET. Non-patent Document No. 1 discloses a CMOSFET structure in which an N-channel-type MOSFET whose channel is made of a Group III-V compound semiconductor and a P-channel-type MOSFET whose channel is made of Ge are formed on a single wafer.
Non-patent Document No. 1: S. Takagi, et al., SSE, vol. 51, p. 526-536, 2007

### SUMMARY OF THE INVENTION

### Problems to be Solved by the Invention

So as to form, on a single wafer, an N-channel-type MISFET (hereinafter simply referred to as “nMISFET”) whose channel is made of a Group III-V compound semiconductor and a P-channel-type MISFET (hereinafter simply referred to as “pMISFET”) whose channel is made of a Group IV semiconductor, there is required a technique to form, on the same wafer, the Group III-V compound semiconductor to be used for the nMISFET and the Group IV semiconductor to be used for the pMISFET. For enabling LSI (Large Scale Integration) production, it is preferable to form a Group III-V compound semiconductor crystal layer to be used for an nMISFET and a Group IV semiconductor crystal layer to be used for a pMISFET on a silicon wafer to which existing production equipment and existing processes are applicable.

So as to inexpensively and efficiently produce as an LSI a CMISFET (Complementary Metal-Insulator-Semiconductor Field-Effect Transistor) made up of an nMISFET and a pMISFET, it is preferable to adopt the production process enabling simultaneous formation of an nMISFET and a pMISFET. Simultaneously forming, in particular, the source/drain of the nMISFET and the source/drain of the pMISFET can simplify the process and easily cope with the need for cost reduction and miniaturization of devices.

The source/drain of the nMISFET and the source/drain of the pMISFET can be simultaneously formed by, for example, forming thin films using materials to become a source and a drain on both of the source/drain formation regions of the nMISFET and the source/drain formation regions of the pMISFET, and then patterning the films by photolithography or the like. The Group III-V compound semiconductor crystal layer from which the nMISFET is formed is, however, different from the Group IV semiconductor crystal layer from which the pMISFET is formed, in constituent material. This increases a resistance of the source/drain regions one or both of the nMISFET and the pMISFET, or increases a contact resistance of the source/drain regions of one or both of the nMISFET and the pMISFET with respect to the source/drain electrodes. It is therefore difficult to reduce a resistance of the source/drain regions of both of the nMISFET and the pMISFET, or a contact resistance of the regions with respect to the source/drain electrodes.

Therefore, it is an object of an aspect of the present invention herein to provide a semiconductor device, and a method for producing a semiconductor device, which can realize simultaneous formation of each source and each drain of an nMISFET and a pMISFET with a smaller resistance in the source/drain regions or a smaller contact resistance of the regions with the source/drain electrodes, when forming, on a single wafer, a CMISFET made up of an nMISFET whose channel is made of a Group III-V compound semiconductor and a pMISFET whose channel is made of a Group IV semiconductor.

### Means for Solving the Problems

In view of the above discussions, according to the first aspect related to the present invention, there is provided a semiconductor device including: a base wafer; a first semiconductor crystal layer positioned above the base wafer; a second semiconductor crystal layer positioned above a partial area of the first semiconductor crystal layer; a first MISFET having a channel formed in a part of an area of the first semiconductor crystal layer above which the second semiconductor crystal layer does not exist and having a first source and a first drain; and a second MISFET having a channel formed in a part of the second semiconductor crystal layer and having a second source and a second drain, where the first MISFET is a first-channel-type MISFET and the second MISFET is a second-channel-type MISFET, the second-channel-type being different from the first-channel-type, the first source, the first drain, the second source, and the second drain are made of the same conductive substance, and the work function Φ_{M} of the conductive substance satisfies at least one of relations respectively represented by (1) φ₁<Φ_{M}<φ₂+E_{g2}, and (2) |Φ_{M}−φ₁|≦0.1 eV and |(φ₂+E_{g2})−Φ_{M}|≦0.1 eV.

Here, φ₁ represents an electron affinity of a crystal constituting a semiconductor crystal layer having a part thereof functioning as an N-type channel, which layer is selected from among the first semiconductor crystal layer and the second semiconductor crystal layer, and φ₂ and E_{g2} represent an electron affinity and a band gap of a crystal constituting a semiconductor crystal having a part thereof functioning as a P-type channel, which layer is selected from among the first semiconductor crystal layer and the second semiconductor crystal layer.

The semiconductor device may further include a first separation layer that is positioned between the base wafer and the first semiconductor crystal layer, and electrically separates the base wafer from the first semiconductor crystal layer; and a second separation layer that is positioned between the first semiconductor crystal layer and the second semiconductor crystal layer, and electrically separates the first semiconductor crystal layer from the second semiconductor crystal layer.

The semiconductor device may further include a second separation layer that is positioned between the first semiconductor crystal layer and the second semiconductor crystal layer, and electrically separates the first semiconductor crystal layer from the second semiconductor crystal layer, where the base wafer is in contact with the first semiconductor crystal layer on a bonding plane, impurity atoms exhibiting a p-type or n-type conductivity type are contained in an area of the base wafer in the vicinity of the bonding plane, and impurity atoms exhibiting a conductivity type different from the conductivity type of impurity atoms contained in the base wafer are contained in an area of the first semiconductor crystal layer in the vicinity of the bonding plane.

The base wafer may be in contact with the first separation layer, and in that case, an area of the base wafer that is in contact with the first separation layer may be conductive, and a voltage applied to the area of the base wafer that is in contact with the first separation layer may function as a back gate voltage with respect to the first MISFET. The first semiconductor crystal layer may be in contact with the second separation layer, and in that case, an area of the first semiconductor crystal layer that is in contact with the second separation layer may be conductive, and a voltage applied to the area of the first semiconductor crystal layer that is in contact with the second separation layer may function as a back gate voltage with respect to the second MISFET.

When the first semiconductor crystal layer is made of a Group IV semiconductor crystal, the first MISFET is preferably a P-channel-type MISFET, and when the second semiconductor crystal layer is made of a Group III-V compound semiconductor crystal, the second MISFET is preferably an N-channel-type MISFET. When the first semiconductor crystal layer is made of a Group III-V compound semiconductor crystal, the first MISFET is preferably an N-channel-type MISFET, and when the second semiconductor crystal layer is made of a Group IV semiconductor crystal, the second MISFET is preferably a P-channel-type MISFET.

Examples of the conductive substance include TiN, TaN, graphene, HfN, or WN.

According to the second aspect related to the present invention, there is provided a semiconductor wafer used for the semiconductor device according to the first aspect, the semiconductor wafer including: the base wafer, the first semiconductor crystal layer, and the second semiconductor crystal layer, where the first semiconductor crystal layer is positioned above the base wafer, and the second semiconductor crystal layer is positioned above a part or all of the first semiconductor crystal layer.

The semiconductor wafer may further include: a first separation layer that is positioned between the base wafer and the first semiconductor crystal layer, and electrically separates the base wafer from the first semiconductor crystal layer; and a second separation layer that is positioned between the first semiconductor crystal layer and the second semiconductor crystal layer, and electrically separates the first semiconductor crystal layer from the second semiconductor crystal layer. In that case, the first separation layer may be made of an amorphous insulator. The first separation layer may also be made of a semiconductor crystal having a wider band gap than a band gap of a semiconductor crystal constituting the first semiconductor crystal layer.

The semiconductor wafer may further include: a second separation layer that is positioned between the first semiconductor crystal layer and the second semiconductor crystal layer, and electrically separates the first semiconductor crystal layer from the second semiconductor crystal layer, where the base wafer may be in contact with the first semiconductor crystal layer on a bonding plane, impurity atoms exhibiting a p-type or n-type conductivity type may be contained in an area of the base wafer in the vicinity of the bonding plane, and impurity atoms exhibiting a conductivity type different from the conductivity type of impurity atoms contained in the base wafer may be contained in an area of the first semiconductor crystal layer in the vicinity of the bonding plane.

The second separation layer may be made of an amorphous insulator. The second separation layer may also be made of a semiconductor crystal having a wider band gap than a band gap of a semiconductor crystal constituting the second semiconductor crystal layer. The semiconductor wafer may further include: a plurality of the second semiconductor crystal layers, where the plurality of second semiconductor crystal layers may be respectively arranged regularly within a plane parallel to an upper plane of the base wafer.

According to the third aspect related to the present invention, there is provided a method for producing the semiconductor wafer according to the second aspect, the method including: first semiconductor crystal layer forming of forming the first semiconductor crystal layer above the base wafer; and second semiconductor crystal layer forming of forming the second semiconductor crystal layer above a partial area of the first semiconductor crystal layer, where the second semiconductor crystal layer forming includes: epitaxial growth of forming the second semiconductor crystal layer on a semiconductor crystal layer forming wafer by epitaxial growth, forming, on the first semiconductor crystal layer, on the second semiconductor crystal layer, or on both of the first semiconductor crystal layer and the second semiconductor crystal layer, a second separation layer that electrically separates the first semiconductor crystal layer from the second semiconductor crystal layer, and bonding the base wafer including the first semiconductor crystal layer to the semiconductor crystal layer forming wafer so that the second separation layer positioned on the first semiconductor crystal layer will be bonded to the second semiconductor crystal layer, that the second separation layer positioned on the second semiconductor crystal layer will be bonded to the first semiconductor crystal layer, or that the second separation layer positioned on the first semiconductor crystal layer will be bonded to the second separation layer positioned on the second semiconductor crystal layer.

The first semiconductor crystal layer forming may include: epitaxial growth of forming the first semiconductor crystal layer on a semiconductor crystal layer forming wafer by epitaxial growth; forming, on the base wafer, on the first semiconductor crystal layer, or on both of the base wafer and the first semiconductor crystal layer, a first separation layer that electrically separates the base wafer from the first semiconductor crystal layer; and bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

When the first semiconductor crystal layer is made of SiGe, and the second semiconductor crystal layer is made of a Group III-V compound semiconductor crystal, the method may include, prior to the first semiconductor crystal layer forming, forming a first separation layer made of an insulator on the base wafer, and the first semiconductor crystal layer forming may include: forming a SiGe layer, which serves as a starting material of the first semiconductor crystal layer, on the first separation layer; and enhancing the concentration of Ge atom in the SiGe layer by heating the SiGe layer in an oxidizing atmosphere to oxidize the surface.

When the first semiconductor crystal layer is made of a Group IV semiconductor crystal, and the second semiconductor crystal layer is made of a Group III-V compound semiconductor crystal, the method may include: forming a first separation layer made of an insulator on a surface of a semiconductor layer material wafer made of a Group IV semiconductor crystal; injecting, via the first separation layer, cations to a predetermined separation depth of the semiconductor layer material wafer; boding the semiconductor layer material wafer to the base wafer, so that a surface of the first separation layer will be bonded to a surface of the base wafer; changing the Group IV semiconductor crystal positioned at the predetermined separation depth by heating the semiconductor layer material wafer and the base wafer, and reacting the cations having been injected to the predetermined separation depth and Group IV atom constituting the semiconductor layer material wafer; separating the semiconductor layer material wafer from the base wafer, thereby detaching, from the semiconductor layer material wafer, the Group IV semiconductor crystal positioned nearer to the base wafer than to the changed portion of the Group IV semiconductor crystal having been changed in the changing; and polishing a crystal layer made of the Group IV semiconductor crystal remaining on the base wafer.

The method for producing may include, prior to the first semiconductor crystal layer forming, forming, on the base wafer, a first separation layer made of a semiconductor crystal having a wider band gap than a band gap of a semiconductor crystal constituting the first semiconductor crystal layer by epitaxial growth, where the first semiconductor crystal layer forming can be to form the first semiconductor crystal layer on the first separation layer by epitaxial growth.

The first semiconductor crystal layer forming may be to form the first semiconductor crystal layer on the base wafer by epitaxial growth. In such a case, impurity atoms exhibiting a p-type or n-type conductivity type may be contained in the vicinity of a surface of the base wafer, and in the forming of the first semiconductor crystal layer by epitaxial growth, the first semiconductor crystal layer may be oped with impurity atoms exhibiting a conductivity type different from a conductivity type of impurity atoms contained in the base wafer.

According to the fourth aspect related to the present invention, there is provided a method for producing the semiconductor wafer according to the fourth aspect, including: second semiconductor crystal layer forming of forming the second semiconductor crystal layer on a semiconductor crystal layer forming wafer by epitaxial growth; second separation layer forming of forming, on the second semiconductor crystal layer, a second separation layer made of a semiconductor crystal having a wider band gap than a band gap of a semiconductor crystal constituting the second semiconductor crystal layer by epitaxial growth; first semiconductor crystal layer forming of forming the first semiconductor crystal layer on the second separation layer by epitaxial growth; forming, on the base wafer, on the first semiconductor crystal layer, or on both of the base wafer and the first semiconductor crystal layer, a first separation layer that electrically separates the base wafer from the first semiconductor crystal layer; and bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

The methods for producing the semiconductor wafer, having been described above according to the third aspect and the fourth aspect may further include: prior to forming a semiconductor crystal layer on the semiconductor crystal layer forming wafer, forming a crystalline sacrificial layer on a surface of the semiconductor crystal layer forming wafer by epitaxial growth; and separating the semiconductor crystal layer forming wafer from the semiconductor crystal layer having been formed by epitaxial growth on the semiconductor crystal layer forming wafer, by removing the crystalline sacrificial layer, after bonding the base wafer to the semiconductor crystal layer forming wafer. The method for producing may include: any one of patterning the second semiconductor crystal layer in a regular arrangement after having formed the second semiconductor crystal layer by epitaxial growth, or forming the second semiconductor crystal layer in a regular arrangement by selective epitaxial growth.

According to the fifth aspect related to the present invention, there is provided a method for producing a semiconductor device, the method including: producing a semiconductor wafer including the first semiconductor crystal layer and the second semiconductor crystal layer by using the method according to the third or fourth aspect for producing the semiconductor wafer; forming a conductive substance whose work function Φ_{M} satisfies at least one of relations respectively represented by (1) φ₁<Φ_{M}<φ₂+E_{g2}, and (2) |Φ_{M}−φ₁|≦0.1 eV and |(φ₂+E_{g2})−Φ_{M}|≦0.1 eV; removing the conductive substance in a region in which a gate electrode is to be formed; forming a gate insulating layer and a gate electrode in the region from which the conductive substance has been removed; and patterning and heating the conductive substance thereby forming a first source and a first drain on both sides of the gate electrode positioned on the first semiconductor crystal and forming a second source and a second drain on both sides of the gate electrode positioned on the second semiconductor crystal.

Here, φ₁ represents an electron affinity of a crystal constituting a semiconductor crystal layer having a part thereof functioning as an N-type channel, which layer is selected from among the first semiconductor crystal layer and the second semiconductor crystal layer, and φ₂ and E_{g2} represent an electron affinity and a band gap of a crystal constituting a semiconductor crystal having a part thereof functioning as a P-type channel, which layer is selected from among the first semiconductor crystal layer and the second semiconductor crystal layer.

### BRIEF DESCRIPTION OF THE DRAWINGS

FIG. 1 shows a cross section of a semiconductor device 100.

FIG. 2 shows a cross section of the semiconductor device 100 in a production process.

FIG. 3 shows a cross section of the semiconductor device 100 in a production process.

FIG. 4 shows a cross section of the semiconductor device 100 in a production process.

FIG. 5 shows a cross section of the semiconductor device 100 in a production process.

FIG. 6 shows a cross section of the semiconductor device 100 in a production process.

FIG. 7 shows a cross section of the semiconductor device 100 in a production process.

FIG. 8 shows a cross section of the semiconductor device 100 in a production process.

FIG. 9 shows a cross section of a different semiconductor device in a production process.

FIG. 10 shows a cross section of a different semiconductor device in a production process.

FIG. 11 shows a cross section of a different semiconductor device in a production process.

FIG. 12 shows a cross section of a still different semiconductor device in a production process.

FIG. 13 shows a cross section of a still different semiconductor device in a production process.

FIG. 14 shows a cross section of a semiconductor device 200.

FIG. 15 is a SEM photograph of nMOSFET observed from above.

FIG. 16 is a TEM photograph showing a cross section of the gate portion of the nMOSFET.

FIG. 17 is a graph showing a characteristic relation between a gate voltage and a source current.

FIG. 18 is a graph showing a characteristic relation between a gate voltage and a source current.

FIG. 19 is a graph showing a characteristic relation between a gate voltage and a source current.

FIG. 20 is a graph showing a SS value with respect to a gate length.

FIG. 21 is a graph showing a DIBL value with respect to a gate length.

### MODE FOR CARRYING OUT THE INVENTION

FIG. 1 shows a cross section of a semiconductor device 100. The semiconductor device 100 includes a base wafer 102, a first semiconductor crystal layer 104, and a second semiconductor crystal layer 106. The semiconductor device 100 according to this example includes a first separation layer 108 that is positioned between the base wafer 102 and the first semiconductor crystal layer 104, and a second separation layer 110 that is positioned between the first semiconductor crystal layer 104 and the second semiconductor crystal layer 106. Note that from the embodiment example illustrated in FIG. 1, at least two inventions can be interpreted; one invention directed to a semiconductor wafer including, as constituting elements, a base wafer 102, a first semiconductor crystal layer 104, and a second semiconductor crystal layer 106, and another invention directed to a semiconductor wafer including, as constituting elements, a base wafer 102, a first separation layer 108, a first semiconductor crystal layer 104, a second separation layer 110, and a second semiconductor crystal layer 106. A first MISFET 120 is formed on the first semiconductor crystal layer 104, and a second MISFET 130 is formed on the second semiconductor crystal layer 106.

An example of the base wafer 102 includes a wafer whose surface is made of silicon crystals. Examples of the wafer whose surface is made of silicon crystals include a silicon wafer and an SOI (Silicon on Insulator) wafer. A silicon wafer is preferable. Using as the base wafer 102 a wafer whose surface is made of silicon crystals enables the utilization of existing production equipment and existing production processes, and can improve the efficiency in R&D and production. The base wafer 102 may also be an insulating wafer such as glass, ceramics, and plastic, a conductive wafer such as metal, or a semiconductor wafer such as silicon carbide, and is not limited to the wafer whose surface is made of silicon crystals.

The first semiconductor crystal layer 104 is provided above the base wafer 102. The first semiconductor crystal layer 104 is made of a Group IV semiconductor crystal or a Group III-V compound semiconductor crystal. The thickness of the first semiconductor crystal layer 104 is preferably equal to or smaller than 20 nm. By making the first semiconductor crystal layer 104 to have the thickness of equal to or smaller than 20 nm, the first MISFET 120 will have an extremely thin film body. By making the body of the first MISFET 120 to be an extremely thin film, the short channel effect can be restrained, and the leak current of the first MISFET 120 can be reduced.

The second semiconductor crystal layer 106 is positioned above a part of the surface of the first semiconductor crystal layer 104. In other words, the second semiconductor crystal layer 106 is positioned above a part of the surface of the first semiconductor crystal layer 104, and a portion of the region of the first semiconductor crystal layer 104 on which no second semiconductor crystal layer 106 exists will function as a channel of the first MISFET 120. The second semiconductor crystal layer 106 is made of a Group III-V compound semiconductor crystal or a Group IV semiconductor crystal. The thickness of the second semiconductor crystal layer 106 is preferably equal to or smaller than 20 nm. By making the second semiconductor crystal layer 106 to have the thickness of equal to or smaller than 20 nm, the second MISFET 130 will have an extremely thin film body. By making the body of the second MISFET 130 to be an extremely thin film, the short channel effect can be restrained, and the leak current of the second MISFET 130 can be reduced.

The electronic mobility is high in the Group III-V compound semiconductor crystal, and the hole mobility is high in the Group IV semiconductor crystal, especially in Ge, and therefore it is preferable to form an N-channel-type MISFET in the Group III-V compound semiconductor crystal layer, and form a P-channel-type MISFET in the Group IV semiconductor crystal layer. In other words, when the first semiconductor crystal layer 104 is made of a Group IV semiconductor crystal, and the second semiconductor crystal layer 106 is made of a Group III-V compound semiconductor crystal, it is preferable to form the first MISFET 120 to be the P-channel-type MISFET, and the second MISFET 130 to be the N-channel-type MISFET.

Conversely, when the first semiconductor crystal layer 104 is made of a Group III-V compound semiconductor crystal, and the second semiconductor crystal layer 106 is made of a Group IV semiconductor crystal, it is preferable to form a first MISFET 120 to be an N-channel-type MISFET, and a second MISFET 130 to be a P-channel-type MISFET. By doing so, the performance of each of the first MISFET 120 and the second MISFET 130 can be enhanced, and the performance of the CMISFET made of the first MISFET 120 and the second MISFET 130 can be maximized.

Examples of the Group IV semiconductor crystal a Ge crystal and a SiₓGe₁₋ₓ (0≦x<1) crystal. When the Group IV semiconductor crystal is the SiₓGe₁₋ₓ crystal, x is preferably equal to or smaller than 0.10. Examples of the Group III-V compound semiconductor crystal include an InₓGa₁₋ₓAs (0<x<1) crystal, an InAs crystal, a GaAs crystal, and an InP crystal. Another example of the Group III-V compound semiconductor crystal includes a mixed crystal of a Group III-V compound semiconductor that lattice-matches or pseudo-lattice-matches GaAs or InP. A still different example of the Group III-V compound semiconductor crystal includes a laminate of the mixed crystal and an InₓGa₁₋ₓAs (0<x<1) crystal, an InAs crystal, a GaAs crystal, or an InP crystal. Note that preferable Group III-V compound semiconductor crystals are an InₓGa₁₋ₓAs (0<x<1) crystal and an InAs crystal, of which an InAs crystal is more preferable.

The first separation layer 108 is positioned between the base wafer 102 and the first semiconductor crystal layer 104. The first separation layer 108 electrically separates the base wafer 102 from the first semiconductor crystal layer 104.

The first separation layer 108 may be made of an amorphous insulator. When forming the first semiconductor crystal layer 104 and the first separation layer 108 by a wafer bonding method, an oxidation condense method, or a smart cut method, the first separation layer 108 will be made of an amorphous insulator. Example of the first separation layer 108 made of an amorphous insulator include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The first separation layer 108 may be made of a semiconductor crystal having a wider band gap than the band gap of the semiconductor crystal constituting the first semiconductor crystal layer 104. Such semiconductor crystal can be formed by an epitaxial crystal growth method. When the first semiconductor crystal layer 104 is an InGaAs crystal layer or a GaAs crystal layer, examples of the semiconductor crystal constituting the first separation layer 108 include an AlGaAs crystal, an AlInGaP crystal, an AlGaInAs crystal, and an InP crystal. When the first semiconductor crystal layer 104 is a Ge crystal layer, examples of the semiconductor crystal constituting the first separation layer 108 include a SiGe crystal, a Si crystal, a SiC crystal, and a C crystal.

The second separation layer 110 is positioned between the first semiconductor crystal layer 104 and the second semiconductor crystal layer 106. The second separation layer 110 electrically separates the first semiconductor crystal layer 104 from the second semiconductor crystal layer 106.

The second separation layer 110 may be made of an amorphous insulator. When forming the second semiconductor crystal layer 106 and the second separation layer 110 by a wafer bonding method, the second separation layer 110 will be an amorphous insulator. Examples of the second separation layer 110 made of an amorphous insulator include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The second separation layer 110 may be made of a semiconductor crystal having a wider band gap than the band gap of the semiconductor crystal constituting the second semiconductor crystal layer 106. Such semiconductor crystal can be formed by an epitaxial crystal growth method. When the second semiconductor crystal layer 106 is an InGaAs crystal layer or a GaAs crystal layer, examples of the semiconductor crystal constituting the second separation layer 110 include an AlGaAs crystal, an AlInGaP crystal, an AlGaInAs crystal, and an InP crystal. When the second semiconductor crystal layer 106 is a Ge crystal layer, examples of the semiconductor crystal constituting the second separation layer 110 include a SiGe crystal, a Si crystal, a SiC crystal, and a C crystal.

The first MISFET 120 is formed on the region of the first semiconductor crystal layer 104 above which no second semiconductor crystal layer 106 is positioned, and has a first gate 122, a first source 124, and a first drain 126. A first gate metal 123 is formed on the first gate 122, and a first source electrode 125 and a first drain electrode 127 are respectively formed on the first source 124 and the first drain 126. Examples of the substance constituting the first gate metal 123, the first source electrode 125, and the first drain electrode 127 include Ti, Ta, W, Al, Cu, Au, or a laminate of them.

The first source 124 and the first drain 126 are made of a conductive substance formed on the first semiconductor crystal layer 104, and form a raised source/drain. Examples of the conductive substance include TiN, TaN, graphene, HfN, or WN. The first gate 122 is formed between the first source 124 and the first drain 126. The first gate 122 is insulated by the insulating layer 114 from the first source 124, the first drain 126, and the first semiconductor crystal layer 104. Examples of the substance constituting the first gate 122 include TiN, TaN, graphene, HfN, or WN. Examples of the insulating layer 114 include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The portion 104a of the first semiconductor crystal layer 104 between the first source 124 and the first drain 126, to which the first gate 122 opposes through the insulating layer 114, functions as a channel of the first MISFET 120. A portion 114a of the insulating layer 114 is formed in the region sandwiched by the portion 104a of the first semiconductor crystal layer 104 and the first gate 122, the portion 104a having been explained above as a channel region. The portion 114a may also function as a gate insulating layer.

The second MISFET 130 is formed on the second semiconductor crystal layer 106, and has a second gate 132, a second source 134, and a second drain 136. A second gate metal 133 is formed on the second gate 132, and a second source electrode 135 and a second drain electrode 137 are respectively formed on the second source 134 and the second drain 136. Examples of the substance constituting the second gate metal 133, the second source electrode 135, and the second drain electrode 137 include Ti, Ta, W, Al, Cu, Au, or a laminate of them.

The second source 134 and the second drain 136 are made of a conductive substance formed on the second semiconductor crystal layer 106, and form a raised source/drain. Examples of the conductive substance include TiN, TaN, graphene, HfN, or WN. The second gate 132 is formed between the second source 134 and the second drain 136. Just as in the case of the first MISFET 120, the second gate 132 is insulated by the insulating layer 114 from the second source 134, the second drain 136, and the second semiconductor crystal layer 106. Examples of the substance constituting the second gate 132 include TiN, TaN, graphene, HfN, or WN.

The portion 106a of the second semiconductor crystal layer 106 between the second source 134 and the second drain 136, to which the second gate 132 opposes through the insulating layer 114, functions as a channel of the second MISFET 130. A portion 114a of the insulating layer 114 is formed in the region sandwiched by the portion 106a of the second semiconductor crystal layer 106 and the second gate 132, the portion 106a having been explained above as a channel region. The portion 114a may also function as a gate insulating layer.

The first source 124, the first drain 126, the second source 134, and the second drain 136 are made of the same conductive substance, and the work function Φ_{M} of the conductive substance satisfies at least one of the relations respectively represented by the following Expression 1 and Expression 2.

φ₁<Φ_{M}<φ₂+E_{g2} Expression 1

|Φ_{M}−φ₁|≦0.1 eV and |(φ₂+E_{g2})−Φ_{M}|≦0.1 eV Expression 2

In the above expressions, φ₁ represents an electron affinity of a crystal constituting a semiconductor crystal layer having a part thereof functioning as an N-type channel, which layer is selected from among the first semiconductor crystal layer 104 and the second semiconductor crystal layer 106, and φ₂ and E_{g2} represent an electron affinity and a band gap of a crystal constituting a semiconductor crystal having a part thereof functioning as a P-type channel, which layer is selected from among the first semiconductor crystal layer 104 and the second semiconductor crystal layer 106. Note that the work function Φ_{M} of the conductive substance may satisfy both of the relations respectively represented by Expression 1 and Expression 2.

As described above, the source/drain (first source 124 and first drain 126) of the first MISFET 120 and the source/drain (second source 134 and second drain 136) of the second MISFET 130 are made of the same conductive substance. This configuration enables production of the portion using the same material film, which means that it becomes possible to simplify the production process. Moreover, the gate widths of the first MISFET 120 and the second MISFET 130 can be easily controlled by taking advantage of the space created between the source/drain (i.e., etching trench interval), which can facilitate miniaturization. Still further, the contact resistance between each source/drain region and the semiconductor crystal layer can be reduced because the work function of the conductive substance constituting the first source 124, the first drain 126, the second source 134, and the second drain 136 satisfies the relation of Expression 1 or Expression 2 described above. For example, when the work function Φ_{M} of the conductive substance satisfies the relation of Expression 1, even the maximum value of the difference between Φ_{M} and φ₁ as well as the maximum value of the difference between Φ_{M} and φ₂+E_{g2} is smaller than the difference between φ₁ and φ₂+E_{g2}. The contact resistance between each source/drain region and the semiconductor crystal layer can be decreased. On the other hand, when the work function Φ_{M} of the conductive substance satisfies the relation of Expression 2, the difference between Φ_{M} and φ₁ as well as the difference between Φ_{M} and φ₂+E_{g2} can be suppressed to be equal to or smaller than 0.1 eV. Accordingly, the contact resistance between each source/drain region and the semiconductor crystal layer can be decreased. This can lead to simplification of the production process of the CMISFET, facilitation of miniaturization, as well as increase in performance of each FET.

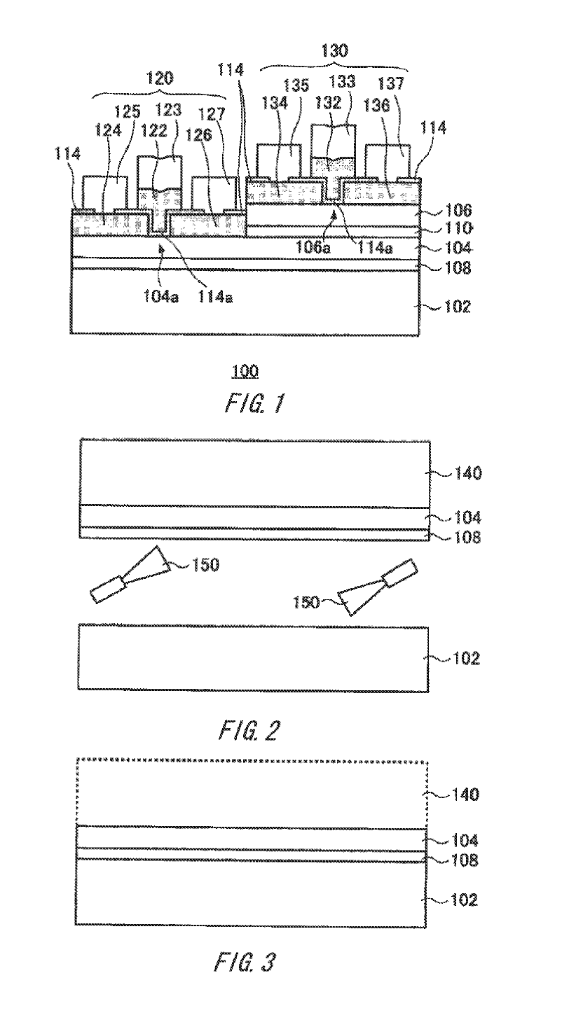

FIG. 2 through FIG. 8 show a cross section of the semiconductor device 100 in a production process. First, a base wafer 102 and a semiconductor crystal layer forming wafer 140 are prepared, and a first semiconductor crystal layer 104 is formed on the semiconductor crystal layer forming wafer 140 by epitaxial crystal growth. Subsequently, a first separation layer 108 is formed on the first semiconductor crystal layer 104. The first separation layer 108 is formed by a thin-film fabrication method such as ALD (Atomic Layer Deposition), thermal oxidation, evaporation, CVD (Chemical Vapor Deposition), and sputtering.

When forming the first semiconductor crystal layer 104 made of a Group III-V compound semiconductor crystal, an InP wafer or a GaAs wafer can be selected as the semiconductor crystal layer forming wafer 140. When forming the first semiconductor crystal layer 104 made of a Group IV semiconductor crystal, a Ge wafer, a Si wafer, a SiC wafer, or a GaAs wafer can be selected as the semiconductor crystal layer forming wafer 140.

MOCVD (Metal Organic Chemical Vapor Deposition) may be used for the epitaxial crystal growth of the first semiconductor crystal layer 104. When forming the Group III-V compound semiconductor crystal layer with the MOCVD method, TMIn (trimethylindium) can be used for an In source, TMGa (trimethylgallium) as a Ga source, AsH₃ (arsine) as an As source, and PH₃ (phosphine) as a P source. Hydrogen can be used as a carrier gas. The reaction temperature can be appropriately adjusted in the range of 300° C. to 900° C., preferably in the range of 450° C. to 750° C. When forming the Group IV compound semiconductor crystal layer with the CVD method, GeH₄ (germane) can be used for a Ge source, and SiH₄ (silane) or Si₂H₆ (disilane) can be used for a Si source. It is also possible to use respective compounds in which a part of the plurality of hydrogen atoms thereof is replaced by a chlorine atom or a hydrocarbon group. Hydrogen can be used as a carrier gas. The reaction temperature can be appropriately adjusted in the range of 300° C. to 900° C., preferably in the range of 450° C. to 750° C. By appropriately adjusting the amount of source gas supply and the reaction time, the thickness of the epitaxial growth layer can be controlled.

As shown in FIG. 2, the surface of the first separation layer 108 and the surface of the base wafer 102 are activated using an argon beam 150. Subsequently, as shown in FIG. 3, the surface of the first separation layer 108 and the surface of the base wafer 102, which have been subjected to the argon beam 150 activation, are bonded to each other. The bonding process can be employed in the room temperature. Note that the activation may be employed using a beam of a different rare gas or the like, and is not necessary limited to the argon beam 150. Subsequently, the semiconductor crystal layer forming wafer 140 is etched away. The first separation layer 108 and the first semiconductor crystal layer 104 are resultantly formed on the base wafer 102. Note that, between the formation of the first semiconductor crystal layer 104 and the formation of the first separation layer 108, sulfur termination may be employed to terminate the surface of the first semiconductor crystal layer 104 using sulfur atoms.

While the first separation layer 108 is formed only on the first semiconductor crystal layer 104, and the surface of the first separation layer 108 is bonded to the surface of the base wafer 102 in the examples shown in FIG. 2 and FIG. 3, the first separation layer 108 may also be formed on the base wafer 102, and the surface of the first separation layer 108 which is provided on the first semiconductor crystal layer 104 may be bonded to the surface of the first separation layer 108 which is provided on the base wafer 102. In such a case, it is preferable to subject, to a hydrophilic treatment, the surfaces of the first separation layers 108 to be bonded. When having employed the hydrophilic treatment, it is preferable to heat and bond the first separation layers 108 to each other. It is alternatively possible to form the first separation layer 108 only on the base wafer 102, and then bond the surface of the first semiconductor crystal layer 104 to the surface of the first separation layer 108 which is provided on the base wafer 102.

While the first separation layer 108 and the first semiconductor crystal layer 104 are bonded to the base wafer 102 and then separated from the semiconductor crystal layer forming wafer 140 in the examples shown in FIG. 2 and FIG. 3, the first separation layer 108 and the first semiconductor crystal layer 104 may be separated from the semiconductor crystal layer forming wafer 140, and then bonded to the base wafer 102. In the latter case, it is preferable to retain the first separation layer 108 and the first semiconductor crystal layer 104 on an adequate transfer wafer during a period after the first separation layer 108 and the first semiconductor crystal layer 104 are separated from the semiconductor crystal layer forming wafer 140 and until they are bonded to the base wafer 102.

Subsequently, the semiconductor crystal layer forming wafer 160 is prepared, and a second semiconductor crystal layer 106 is formed on the semiconductor crystal layer forming wafer 160 by epitaxial crystal growth. In addition, a second separation layer 110 is formed on the first semiconductor crystal layer 104 provided on the base wafer 102. The second separation layer 110 is formed by a thin-film fabrication method such as ALD, thermal oxidation, evaporation, CVD, and sputtering. Note that, prior to the formation of the second separation layer 110, sulfur termination may be employed to terminate the surface of the first semiconductor crystal layer 104 using sulfur atoms.

When forming the second semiconductor crystal layer 106 made of a Group III-V compound semiconductor crystal, an InP wafer or a GaAs wafer can be selected as the semiconductor crystal layer forming wafer 160. When forming the second semiconductor crystal layer 106 made of a Group IV semiconductor crystal, a Ge wafer, a Si wafer, a SiC wafer, or a GaAs wafer can be selected as the semiconductor crystal layer forming wafer 160.

MOCVD (Metal Organic Chemical Vapor Deposition) can be used for the epitaxial crystal growth of the second semiconductor crystal layer 106. The conditions such as gas or reaction temperature used in the MOCVD are the same as those adopted in the case of the first semiconductor crystal layer 104.

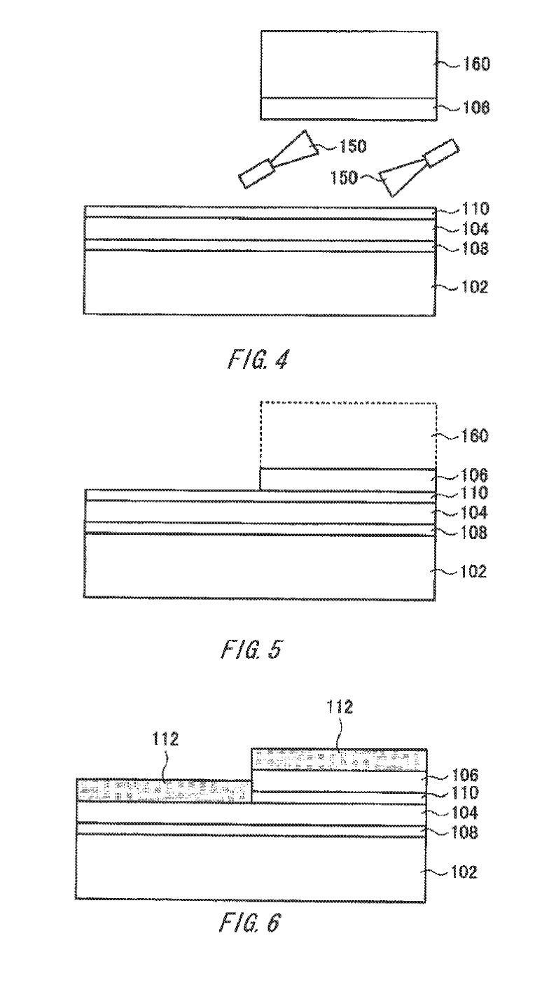

As shown in FIG. 4, the surface of the second semiconductor crystal layer 106 and the surface of the second separation layer 110 are activated using an argon beam 150. Subsequently, as shown in FIG. 5, the surface of the second semiconductor crystal layer 106 is bonded to a part of the surface of the second separation layer 110. The bonding process can be employed in the room temperature. The activation may be employed using a beam of a different rare gas or the like, and is not necessary limited to the argon beam 150. Subsequently, the semiconductor crystal layer forming wafer 160 is etched away using an HCl solution or the like. The second separation layer 110 is resultantly formed on the first semiconductor crystal layer 104 provided on the base wafer 102, and the second semiconductor crystal layer 106 is resultantly formed on a part of the surface of the second separation layer 110. Note that, prior to the bonding process between the second separation layer 110 and the first semiconductor crystal layer 104, sulfur termination may be employed to terminate the surface of the second semiconductor crystal layer 106 using sulfur atoms.

While the second separation layer 110 is formed only on the first semiconductor crystal layer 104, and the surface of the second separation layer 110 is bonded to the surface of the second semiconductor crystal layer 106 in the examples shown in FIG. 4, the second separation layer 110 may also be formed on the second semiconductor crystal layer 106, and the surface of the second separation layer 110 which is provided on the first semiconductor crystal layer 104 may be bonded to the surface of the second separation layer 110 which is provided on the second semiconductor crystal layer 106. In such a case, it is preferable to subject, to a hydrophilic treatment, the surfaces of the second separation layers 110 to be bonded. When having employed the hydrophilic treatment, it is preferable to heat and bond the second separation layers 110 with each other. It is alternatively possible to form the second separation layer 110 only on the second semiconductor crystal layer 106, and then bond the surface of the first semiconductor crystal layer 104 to the surface of the second separation layer 110 which is provided on the second semiconductor crystal layer 106.

While the second semiconductor crystal layer 106 is bonded to the second separation layer 110 provided on the base wafer 102 and then separated from the semiconductor crystal layer forming wafer 160 in the examples shown in FIG. 4, the second semiconductor crystal layer 106 may be separated from the semiconductor crystal layer forming wafer 160, and then bonded to the second separation layer 110. In the latter case, it is preferable to retain the second semiconductor crystal layer 106 on an adequate transfer wafer, during a period after the second semiconductor crystal layer 106 is separated from the semiconductor crystal layer forming wafer 160 and until it is bonded to the second separation layer 110.

Next, as shown in FIG. 6, a conductive substance layer 112 is formed on the first semiconductor crystal layer 104 and the second semiconductor crystal layer 106. The conductive substance layer 112 will eventually be the first source 124, the first drain 126, the second source 134, and the second drain 136. The conductive substance layer 112 is formed by, for example, a thin-film fabrication method such as evaporation, CVD, and sputtering. Note that in FIG. 6, the conductive substance layers 112 respectively in the first MISFET 120 and the second MISFET 130 are separated from each other, by the thickness of the second separation layer 110 and the second semiconductor crystal layer 106. In other examples, it is possible to separate the conductive substance layer 112 between the first MISFET 120 and the second MISFET 130, by utilizing the method such as etching a part of the conductive substance layer 112.

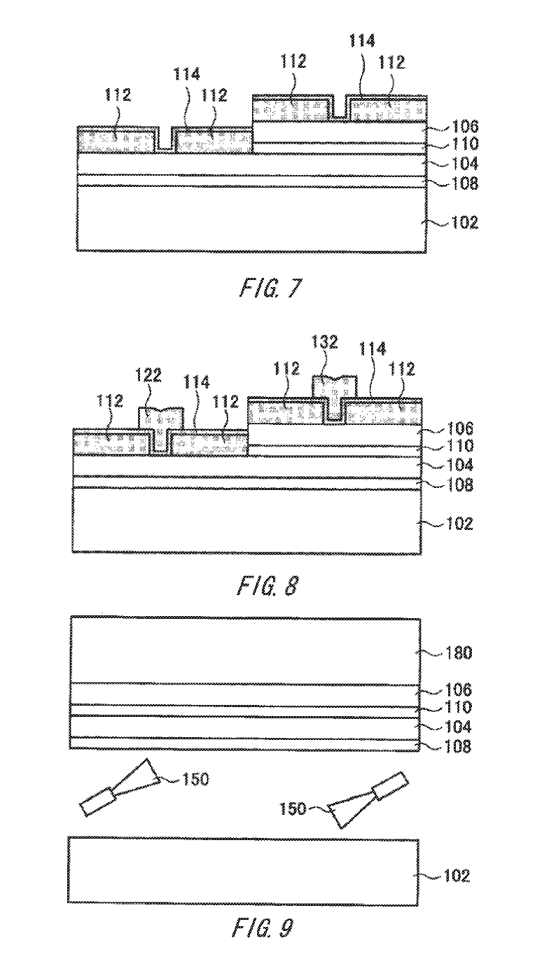

As shown in FIG. 7, the conductive substance layer 112 in the region in which the first gate 122 and the second gate 132 are formed is etched away, thereby forming an aperture. An insulating layer 114 is then formed on the conductive substance layer 112 and inside the aperture. The insulating layer 114 is formed by, for example, a thin-film fabrication method such as ALD, thermal oxidation, evaporation, CVD, and sputtering.

As shown in FIG. 8, a conductive thin-film is formed on the insulating layer 114, and the conductive thin-film existing on any regions other than the region to be the first gate 122 and the second gate 132 is removed, to form the first gate 122 and the second gate 132. Note that the conductive substance layer 112 separated by either the first gate 122 or the second gate 132 will be the first source 124, the first drain 126, the second source 134, and the second drain 136. An aperture is formed through the insulating layer 114, so as to expose the conductive substance layer 112 which will be the first source 124, the first drain 126, the second source 134, and the second drain 136, and the first gate metal 123, the first source electrode 125, and the first drain electrode 127, as well as the second gate metal 133, the second source electrode 135, and the second drain electrode 137 are formed by forming and patterning a conductive thin-film to produce the semiconductor device 100 as shown in FIG. 1. In addition, when a metal film is formed as the conductive thin-film, it is preferable to subject it to post metal annealing. The post metal annealing treatment may preferably be implemented by means of RTA (rapid thermal annealing).

According to the above-explained semiconductor device 100 and its production method, the first source 124, the first drain 126, the second source 134, and the second drain 136 can be simultaneously formed by the same process, and so the production process can be simplified. The production cost can be resultantly reduced, and the miniaturization can be employed easily. Moreover, the work function of the conductive substance constituting the first source 124, the first drain 126, the second source 134, and the second drain 136 satisfies the relation of Expression 1 or the relation of Expression 2. Accordingly, the contact of the first source 124 and the first drain 126 in relation to the first semiconductor crystal layer 104 becomes an ohmic contact, and the contact of the second source 134 and the second drain 136 in relation to the second semiconductor crystal layer 106 becomes an ohmic contact. The on-current of the first MISFET 120 and the second MISFET 130 can be resultantly increased. In addition, the resistance between each source/drain will be small, and so it becomes unnecessary to lower the channel resistance of each MISFET, and the concentration of the doping impurity atoms of the channel layer can be lowered. Consequently, the mobility of the carrier in the channel layer can be enhanced.

In the semiconductor device 100 explained above, the base wafer 102 is in contact with the first separation layer 108, and so, if the region of the base wafer 102 in contact with the first separation layer 108 has a conductive property, a voltage can be applied on the region of the base wafer 102 in contact with the first separation layer 108, and the mentioned voltage can be used as a back gate voltage for the first MISFET 120. Moreover in the semiconductor device 100 explained above, the first semiconductor crystal layer 104 is in contact with the second separation layer 110, and so, if the region of the first semiconductor crystal layer 104 in contact with the second separation layer 110 has a conductive property, a voltage can be applied on the region of the first semiconductor crystal layer 104 in contact with the second separation layer 110, and the mentioned voltage can be used as a back gate voltage for the second MISFET 130. These back gate voltages function to increase the on-current for the first MISFET 120 and the second MISFET 130, and to decrease the off-current therefor.

In the semiconductor device 100 explained above, there may be a plurality of second semiconductor crystal layers 106, and the plurality of second semiconductor crystal layers 106 may be respectively arranged regularly within a plane parallel to an upper plane of the base wafer 102. Here, the term “regularly” may be defined as a repetition of the same arrangement patterns. In addition, the semiconductor device 100 may include a plurality of first semiconductor crystal layers 104, and the plurality of first semiconductor crystal layers 104 may be respectively arranged regularly within a plane parallel to an upper plane of the base wafer 102. In this case, each of the first semiconductor crystal layers 104 may include a single second semiconductor crystal layer 106 or a plurality of second semiconductor crystal layers 106, and each second semiconductor crystal layer 106 may be arranged regularly within a plane parallel to an upper plane of the first semiconductor crystal layer 104. As explained above, by regularly arranging the first semiconductor crystal layers 104 or the second semiconductor crystal layers 106, it becomes possible to enhance the productivity of the semiconductor wafer used for the semiconductor device 100. The regular arrangement of the second semiconductor crystal layers 106 or the first semiconductor crystal layers 104 may be achieved by one of: a method to pattern the second semiconductor crystal layers 106 or the first semiconductor crystal layers 104 in a regular arrangement after forming the second semiconductor crystal layers 106 or the first semiconductor crystal layers 104 by epitaxial growth; a method for forming the second semiconductor crystal layers 106 or the first semiconductor crystal layers 104 in a regular arrangement in advance by selective epitaxial growth; and a method for forming one or both of the second semiconductor crystal layers 106 and the first semiconductor crystal layers 104 on the semiconductor crystal layer forming wafer 160 by epitaxial growth, then separating the one or both of the second semiconductor crystal layers 106 and the first semiconductor crystal layers 104 from the semiconductor crystal layer forming wafer 160, then shaping the one or both of the second semiconductor crystal layers 106 and the first semiconductor crystal layers 104 into a prescribed shape, and then bonding the one or both of the second semiconductor crystal layers 106 and the first semiconductor crystal layers 104 to the base wafer 102 in a regular arrangement. The mentioned arrangement may also be achieved by a combination of a plurality of the methods listed above.

In the aforementioned semiconductor device 100, the first semiconductor crystal layer 104 and the first separation layer 108 are formed on the semiconductor crystal layer forming wafer 140, then the first separation layer 108 is bonded to the base wafer 102, and then the semiconductor crystal layer forming wafer 140 is removed therefrom to form the first semiconductor crystal layer 104 and the first separation layer 108 on the base wafer 102. On the other hand, when forming the first semiconductor crystal layer 104 made of SiGe and the second semiconductor crystal layer 106 made of a Group III-V compound semiconductor crystal, the first semiconductor crystal layer 104 and the first separation layer 108 can be formed by an oxidation condense method. Specifically in this method, prior to the formation of the first semiconductor crystal layer 104, the first separation layer 108 made of an insulator is formed on the base wafer 102 and a SiGe layer is formed on the first separation layer 108, as a starting material of the first semiconductor crystal layer 104. The SiGe layer is heated in an oxidized atmosphere, to oxidize its surface. By oxidizing the SiGe layer, the concentration of the Ge atoms in the SiGe layer will increase, and so a first semiconductor crystal layer 104 having a higher Ge concentration can be obtained.

Alternatively, when forming the first semiconductor crystal layer 104 made of a Group IV semiconductor crystal and the second semiconductor crystal layer 106 made of a Group III-V compound semiconductor crystal, the first semiconductor crystal layer 104 and the first separation layer 108 can be formed using a smart-cut method. Specifically, a first separation layer 108 made of an insulator is formed on the surface of the semiconductor layer material wafer made of a Group IV semiconductor crystal, and cations are injected through the first separation layer 108 to the predetermined separation depth of the semiconductor layer material wafer. Then the semiconductor layer material wafer is bonded to the base wafer 102 so that the surface of the first separation layer 108 will be bonded to the surface of the base wafer 102, and the semiconductor layer material wafer and the base wafer 102 are heated. By this heating process, the cations injected to the predetermined separation depth and the Group IV atoms constituting the semiconductor layer material wafer react to each other, to change the Group IV semiconductor crystal positioned at the predetermined separation depth. By separating the semiconductor layer material wafer from the base wafer 102 in this state, the Group IV semiconductor crystal positioned nearer to the base wafer 102 than to the changed portion of the Group IV semiconductor crystal will be detached from the semiconductor layer material wafer. By subjecting this semiconductor layer material attached nearer to the base wafer 102 to an adequate polishing process, the polished semiconductor crystal layer will be the first semiconductor crystal layer 104.

In the aforementioned semiconductor device 100, when the first separation layer 108 is made of a semiconductor crystal having a wider band gap than a band gap of a semiconductor crystal constituting the first semiconductor crystal layer 104, the first separation layer 108 can be formed by epitaxial growth on the base wafer 102, and the first semiconductor crystal layer 104 can be formed by epitaxial growth on the first separation layer 108. Because the first separation layer 108 and the first semiconductor crystal layer 104 can be created sequentially by means of epitaxial growth, the production process can be simplified.

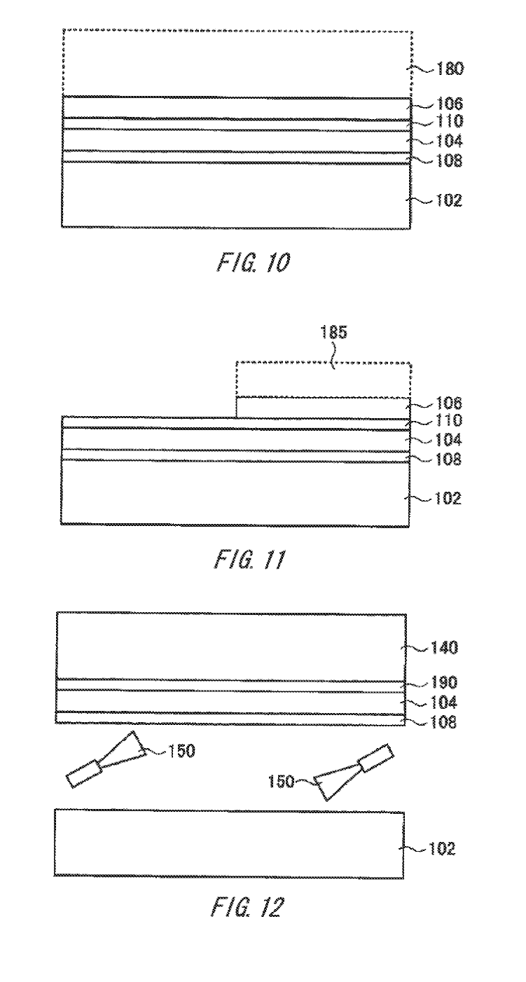

In the aforementioned semiconductor device 100, when the second separation layer 110 is made of a semiconductor crystal having a wider band gap than a band gap of a semiconductor crystal constituting the second semiconductor crystal layer 106, the second semiconductor crystal layer 106, the second separation layer 110, and the first semiconductor crystal layer 104 can be created sequentially by means of epitaxial growth. Specifically, as shown in FIG. 9, the second semiconductor crystal layer 106 is formed by epitaxial growth on the semiconductor crystal layer forming wafer 180, the second separation layer 110 is formed by epitaxial growth on the second semiconductor crystal layer 106, and the first semiconductor crystal layer 104 is formed by epitaxial growth on the second separation layer 110. The aforementioned epitaxial growth processes can be employed sequentially. The first separation layer 108 is formed on the first semiconductor crystal layer 104, and the surface of the first separation layer 108 and the surface of the base wafer 102 are activated using an argon beam 150. Subsequently, as shown in FIG. 10, the surface of the first separation layer 108 is bonded to the surface of the base wafer 102, and the semiconductor crystal layer forming wafer 180 is etched away using an HCl solution or the like. Further, as shown in FIG. 11, a mask 185 is used for etching a part of the second semiconductor crystal layer 106, thereby obtaining a semiconductor wafer similar to FIG. 5. According to the above-explained method, because the second semiconductor crystal layer 106, the second separation layer 110, and the first semiconductor crystal layer 104 can be created sequentially by epitaxial growth, the production process can be simplified.

In the bonding process described above in relation to FIG. 9 and FIG. 10, a first separation layer 108 may be formed on one or both of the base wafer 102 and the first semiconductor crystal layer 104, just as in the case of FIG. 2 and FIG. 3. It is also possible to transfer the first separation layer 108, the first semiconductor crystal layer 104, the second separation layer 110, and the second semiconductor crystal layer 106 to an adequate transfer wafer, and subsequently bond them to the base wafer 102. When the second separation layer 110 is an epitaxially grown crystal, the first semiconductor crystal layer 104, the second separation layer 110, and the second semiconductor crystal layer 106 may be bonded to the base wafer 102, and subsequently the second separation layer 110 may be oxidized to convert it into an amorphous insulating layer. For example when the second separation layer 110 is AlAs or AlInP, the second separation layer 110 can be subjected to a selective oxidation technology to change the second separation layer 110 to an insulating oxide.

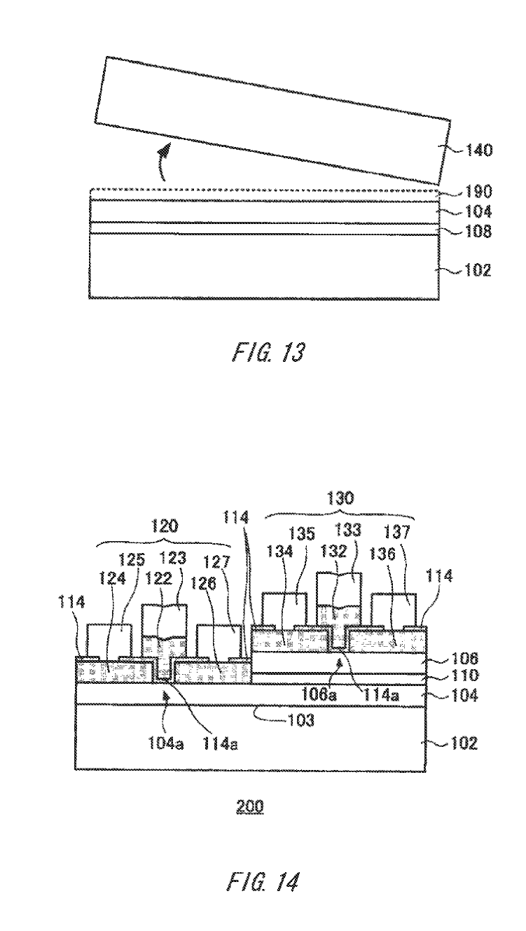

While the semiconductor crystal layer forming wafer is etched away in the bonding process in the production method for the semiconductor device 100 described above, the semiconductor crystal layer forming wafer can be removed by using a crystalline sacrificial layer 190, as shown in FIG. 12. Specifically, prior to forming the first semiconductor crystal layer 104 on the semiconductor crystal layer forming wafer 140, a crystalline sacrificial layer 190 is formed by epitaxial growth on the surface of the semiconductor crystal layer forming wafer 140. Thereafter, the first semiconductor crystal layer 104 and the first separation layer 108 are formed on the surface of the crystalline sacrificial layer 190 by epitaxial growth, and an argon beam 150 is used to activate the surface of the first separation layer 108 and the surface of the base wafer 102. Subsequently, the surface of the first separation layer 108 is bonded to the surface of the base wafer 102, and the crystalline sacrificial layer 190 is removed, as shown in FIG. 13. The first semiconductor crystal layer 104 and the first separation layer 108 provided on the semiconductor crystal layer forming wafer 140 are resultantly separated from the semiconductor crystal layer forming wafer 140. According to this method, a semiconductor crystal layer forming wafer can be recycled, to lead to reduction in production cost.

FIG. 14 shows a cross section of a semiconductor device 200. The semiconductor device 200 does not include the first separation layer 108 of the semiconductor device 100, and the first semiconductor crystal layer 104 is provided to be in contact with the base wafer 102. Since the semiconductor device 200 has the same configuration as the semiconductor device 100 except for the lack of the first separation layer 108, the common elements or the like are not explained in the following.

In the semiconductor device 200, the base wafer 102 is in contact with the first semiconductor crystal layer 104 on the bonding plane 103, impurity atoms exhibiting a p-type or n-type conductivity type are contained in an area of the base wafer 102 in the vicinity of the bonding plane 103, and impurity atoms exhibiting a conductivity type different from the conductivity type of impurity atoms contained in the base wafer 102 are contained in an area of the first semiconductor crystal layer 104 in the vicinity of the bonding plane 103. In other words, the semiconductor device 200 includes a pn junction in the vicinity of the bonding plane 103. This indicates that even in a structure without the first separation layer 108, the pn junction formed in the vicinity of the bonding plane 103 can allow the base wafer 102 to be electrically separated from the first semiconductor crystal layer 104, and to allow the first MISFET 120 formed on the first semiconductor crystal layer 104 to be electrically separated from the base wafer 102.

The mentioned separation method that utilizes the pn junction can also be adopted for the separation between the first semiconductor crystal layer 104 and the second semiconductor crystal layer 106. Specifically, in a structure without the second separation layer 110 and whose first semiconductor crystal layer 104 is in contact with the second semiconductor crystal layer 106 via a bonding plane, impurity atoms exhibiting a p-type or n-type conductivity type are contained in an area of the first semiconductor crystal layer 104 in the vicinity of the bonding plane, and impurity atoms exhibiting a conductivity type different from the conductivity type of impurity atoms contained in the first semiconductor crystal layer 104 are contained in an area of the second semiconductor crystal layer 106 in the vicinity of the bonding plane. Consequently, the first semiconductor crystal layer 104 can be electrically separated from the second semiconductor crystal layer 106, and the first MISFET 120 formed on the first semiconductor crystal layer 104 can be electrically separated from the second MISFET 130 formed on the second semiconductor crystal layer 106.

The semiconductor device 200 can also be produced by replacing the processes after the process of forming the first semiconductor crystal layer 104 on the base wafer 102 by epitaxial growth and the second separation layer 110 on the first semiconductor crystal layer 104, with the similar processes as in the case of the semiconductor device 100. Note that the pn junction can be formed by doping the first semiconductor crystal layer 104 with impurity atoms exhibiting a conductivity type different from the conductivity type of impurity atoms contained in the base wafer, in the process of making the wafer 102 contain impurity atoms exhibiting a p-type or n-type conductivity type in the vicinity of the surface of the base wafer 102, and forming the first semiconductor crystal layer 104 by epitaxial growth.

In the structure in which the first semiconductor crystal layer 104 is formed directly on the base wafer 102, when the isolation is unnecessary, it is not necessary to form the pn junction as an isolation structure. In other words, the semiconductor device 200 may have such a structure that does not include any impurity atoms exhibiting a p-type or n-type conductivity type in an area of the base wafer 102 in the vicinity of the bonding plane 103, and does not include any impurity atoms exhibiting a p-type or n-type conductivity type in an area of the first semiconductor crystal layer 104 in the vicinity of the bonding plane 103.

When forming the first semiconductor crystal layer 104 directly on the base wafer 102, an annealing treatment can be employed either after or during the epitaxial growth process. By employing the annealing treatment, the dislocation contained in the first semiconductor crystal layer 104 will be decreased. The epitaxial growth process may be either a method to grow the first semiconductor crystal layer 104 uniformly on the entire surface of the base wafer 102, or a selective growth method that divides the surface of the base wafer 102 minutely using the growth inhibiting layer made of SiO₂, or the like.

### Embodiment Example

The following embodiment example utilizes a semiconductor wafer that includes a Ge crystal layer above a part of the surface of the base wafer, and an InGaAs crystal layer above another part of the surface of the base wafer over which no Ge crystal layer exists. Therefore, this embodiment example differs, in configuration, from the semiconductor wafer of the present invention, which includes the first semiconductor crystal layer 104 on the base wafer 102 and the second semiconductor crystal layer 106 on the first semiconductor crystal layer 104. However, the following embodiment example can also generate a similar result to the configuration of the semiconductor device 100 explained in relation to FIG. 1, in that they both can simplify the production process of a plurality of source/drain regions, facilitate the miniaturization of the gates, and enhance the performance of each FET. For example, when the first semiconductor crystal layer 104 and the second semiconductor crystal layer 106 of the present invention are a Ge crystal layer and an InGaAs crystal layer respectively, the same advantages as explained above are expected to result. This is why we introduce the following embodiment example for exemplifying the effects that the present invention is expected to generate.

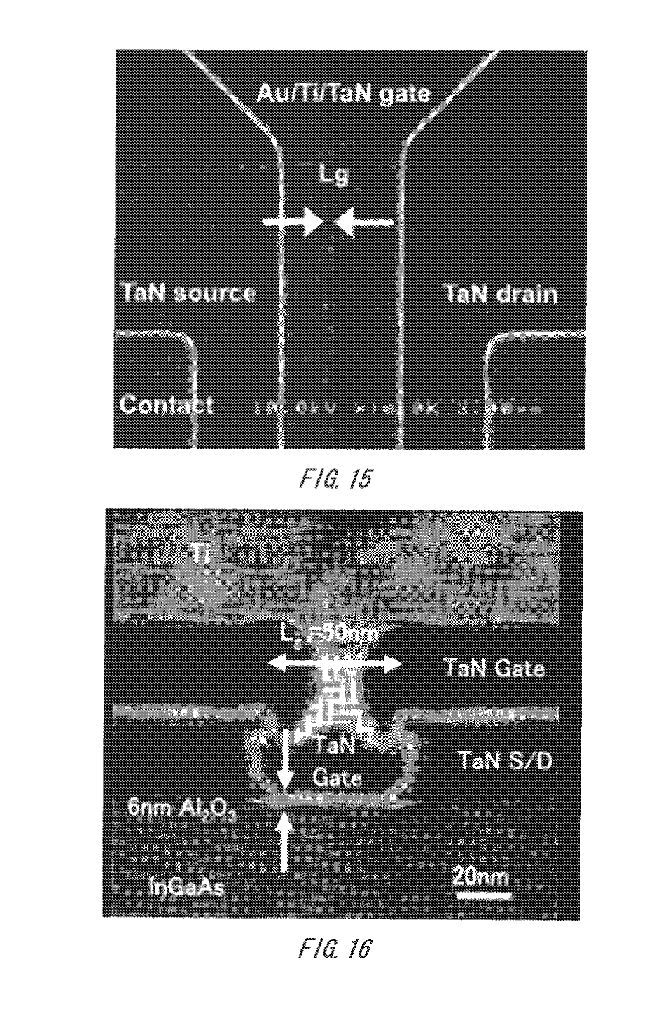

A Ge crystal layer was formed on a part of the surface of a base wafer, and an InGaAs crystal layer was formed on another part of the surface of the base wafer on which no Ge crystal layer was formed. A TaN layer having the thickness of 30 nm was deposited on the InGaAs Crystal layer and the Ge crystal layer, and then the TaN layer was patterned to respectively form a source and a drain on the InGaAs crystal layer and the Ge crystal layer. Al₂O₃ and TaN were deposited in this order to fill the trenches between the source/drain regions, to deposit an Al₂O₃/TaN layer, and then this deposition layer was patterned to form a gate insulating film and a gate. Four types of devices respectively having a trench width (i.e., gate length) between the source and the drain of 50 nm, 75 nm, 100 nm, and 100 μm were formed. As stated above, an nMOSFET was formed on the InGaAs crystal layer, and a pMOSFET was formed on the Ge crystal layer by a process to simultaneously form the source/drain regions. FIG. 15 is a SEM photograph of the nMOSFET observed from above. A gate electrode is formed to overlap with the gap denoted by Lg (the trench between the source and the drain). FIG. 16 is a TEM photograph showing a cross section of the gate portion of the nMOSFET. From this photograph, it is confirmed that the trench between the source and the drain is filled up even when the gate length L is 50 nm.

The source/drain of TaN formed as explained above has a work function of about 4.6 eV. On the other hand, the electronic affinity of InGaAs is 4.5 eV, the electronic affinity of Ge is 4.0 eV, and the band gap of Ge is 0.67 eV. Therefore, the work function Φ_{M} of the source/drain, the electronic affinity φ₁ of InGaAs which is an nMOSFET material, and the sum φ₂+E_{g2} of the electronic affinity of Ge which is a pMOSFET material and its band gap satisfy the relation φ₁<Φ_{M}<φ₂+E_{g2}. In addition, the difference |Φ_{M}−φ₁| between the work function Φ_{M} of the source/drain and the electronic affinity φ₁ of the InGaAs is equal to or smaller than 0.1 eV, and the difference |(φ₂+E_{g2})−Φ_{M}| between the work function Φ_{M} of the source/drain and the sum of the electronic affinity and the band gap of Ge (i.e., φ₂+E_{g2}) is also equal to or smaller than 0.1 eV. Therefore, the barrier between TaN and InGaAs in n-type conduction is low, and also the barrier between TaN and Ge in p-type conduction is low. The contact resistance of the source/drain can be reduced by adopting TaN as a common electrode material for the source/drain regions for both of nMOSFET on the InGaAs crystal layer and pMOSFET on the Ge crystal layer.

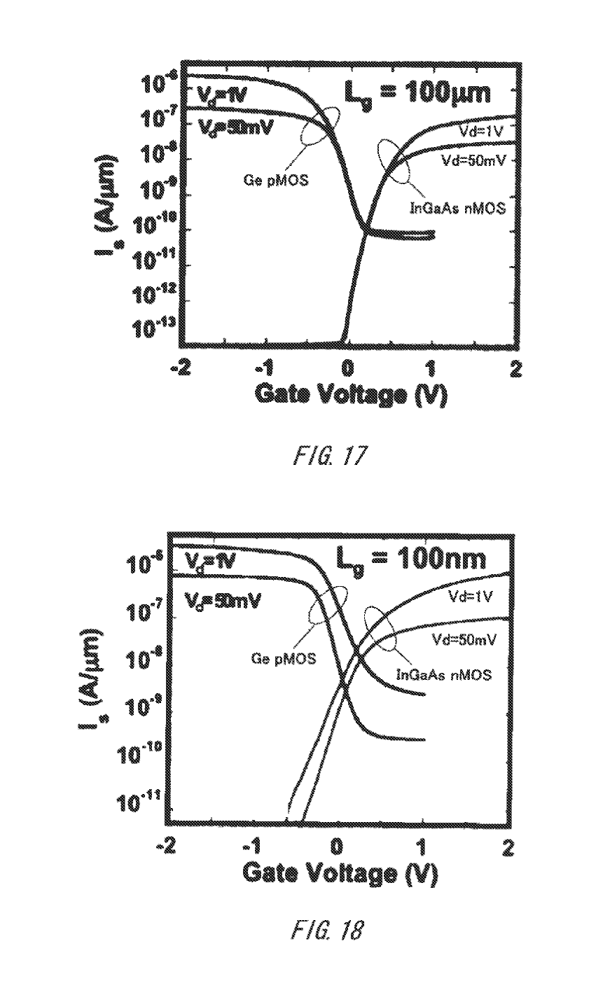

FIG. 17 and FIG. 18 are respectively a graph showing a characteristic relation between a gate voltage and a source current for the pMOSFET and nMOSFET in the Embodiment Example 1, where FIG. 17 relates to the gate length Lg of 100 μm and FIG. 18 relates to the gate length Lg of 100 nm. Each of these figures shows two types of data resulting when the drain voltage Vd is 1 V and 50 mV, respectively. When Lg was 100 μm, a 4 digit on-off ratio was observed at pMOSFET on the Ge crystal layer, and a 6 digit on-off ratio was observed at nMOSFET on the InGaAs crystal layer.

FIG. 19 is a graph showing a characteristic relation between a gate voltage and a source current, and specifically shows data relating to nMOSFET on the InGaAs crystal layer, when the gate length Lg is further reduced compared to FIG. 18. The switching characteristics was observed even in the case of a 50 nm gate length, while the short channel effect raises the off-current and deteriorates the sub-threshold characteristics (SS value).

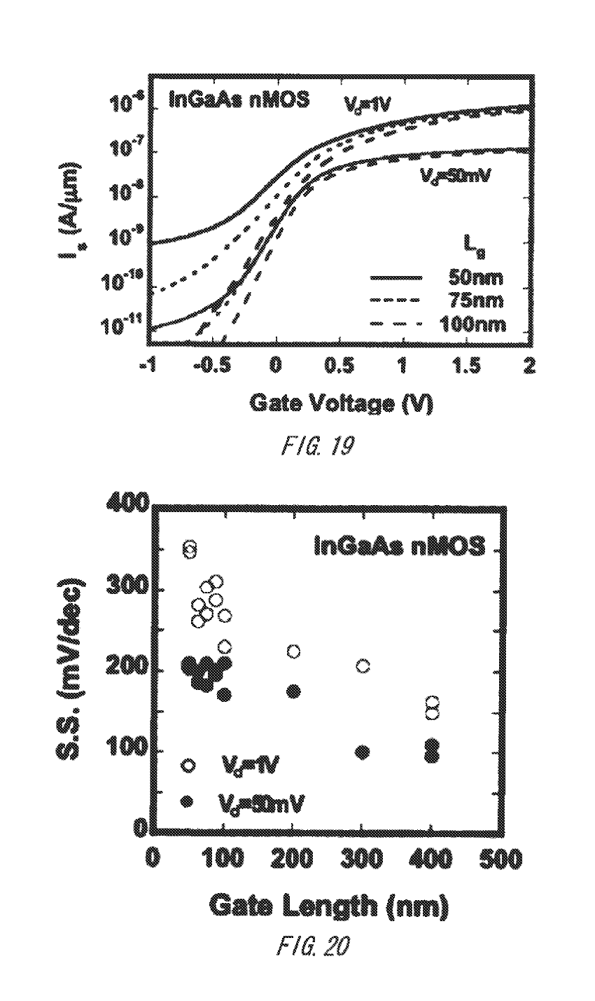

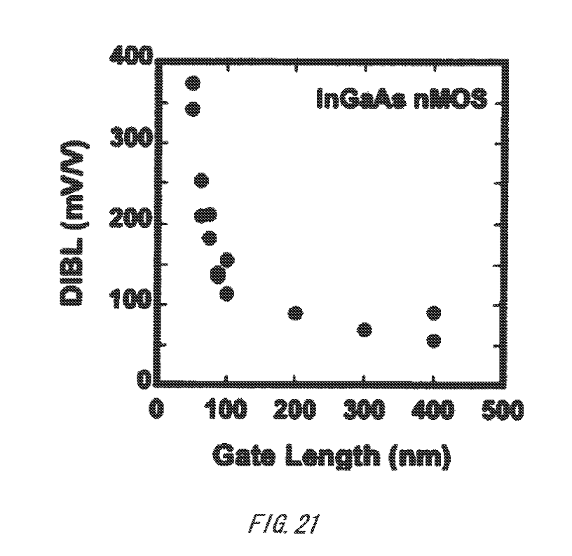

FIG. 20 is a graph showing a SS value with respect to a gate length, and FIG. 21 is a graph showing a DIBL (drain-induced barrier lowering) value with respect to a gate length. Preferable values were obtained; SS=200 mV/dec and DIBL=150 mV/V, when the gate length was 100 nm.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order. In addition, such a phrase as “a first layer is “above” a second layer” includes both cases in which the first layer is provided to be in contact with the upper plane of the second layer, and there is another layer interposed between the lower plane of the first layer and the upper plane of the second layer. The terms related to directions (e.g., “upper”, “lower”) respectively show relative directions in a semiconductor wafer and a semiconductor device, and should not be interpreted as absolute directions in relation to the outside reference plane such as the ground surface.

What is claimed is:

1. A semiconductor device comprising:
a base wafer;
a first semiconductor crystal layer positioned above the base wafer;
a second semiconductor crystal layer positioned above a partial area of the first semiconductor crystal layer;
a first MISFET having a channel formed in a part of an area of the first semiconductor crystal layer above which the second semiconductor crystal layer does not exist and having a first source and a first drain; and
a second MISFET having a channel formed in a part of the second semiconductor crystal layer and having a second source and a second drain, wherein
the first MISFET is a first-channel-type MISFET and the second MISFET is a second-channel-type MISFET, the second-channel-type being different from the first-channel-type,
the first source, the first drain, the second source, and the second drain are made of the same conductive substance, and
the work function Φ_{M} of the conductive substance satisfies at least one of relations respectively represented by (1) φ₁<Φ_{M}<φ₂+E_{g2}, and (2) |Φ_{M}−φ₁|≦0.1 eV and |(φ₂+E_{g2})−Φ_{M}|≦0.1 eV,
where φ₁ represents an electron affinity of a crystal constituting a semiconductor crystal layer having a part thereof functioning as an N-type channel, which layer is selected from among the first semiconductor crystal layer and the second semiconductor crystal layer, and φ₂ and E_{g2} represent an electron affinity and a band gap of a crystal constituting a semiconductor crystal having a part thereof functioning as a P-type channel, which layer is selected from among the first semiconductor crystal layer and the second semiconductor crystal layer.

2. The semiconductor device according to claim 1, further comprising:
a first separation layer that is positioned between the base wafer and the first semiconductor crystal layer, and electrically separates the base wafer from the first semiconductor crystal layer; and
a second separation layer that is positioned between the first semiconductor crystal layer and the second semiconductor crystal layer, and electrically separates the first semiconductor crystal layer from the second semiconductor crystal layer.

3. The semiconductor device according to claim 1, further comprising:
a second separation layer that is positioned between the first semiconductor crystal layer and the second semiconductor crystal layer, and electrically separates the first semiconductor crystal layer from the second semiconductor crystal layer, wherein
the base wafer is in contact with the first semiconductor crystal layer on a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the first semiconductor crystal layer in the vicinity of the bonding plane.

4. The semiconductor device according to claim 2, wherein
the base wafer is in contact with the first separation layer,
an area of the base wafer that is in contact with the first separation layer is conductive, and
a voltage applied to the area of the base wafer that is in contact with the first separation layer functions as a back gate voltage with respect to the first MISFET.

5. The semiconductor device according to claim 2, wherein
the first semiconductor crystal layer is in contact with the second separation layer,
an area of the first semiconductor crystal layer that is in contact with the second separation layer is conductive, and
a voltage applied to the area of the first semiconductor crystal layer that is in contact with the second separation layer functions as a back gate voltage with respect to the second MISFET.

6. The semiconductor device according to claim 1, wherein
the first semiconductor crystal layer is made of a Group IV semiconductor crystal, and the first MISFET is a P-channel-type MISFET, and
the second semiconductor crystal layer is made of a Group III-V compound semiconductor crystal, and the second MISFET is an N-channel-type MISFET.

7. The semiconductor device according to claim 1, wherein
the first semiconductor crystal layer is made of a Group III-V compound semiconductor crystal, and the first MISFET is an N-channel-type MISFET, and
the second semiconductor crystal layer is made of a Group IV semiconductor crystal, and the second MISFET is a P-channel-type MISFET.

8. The semiconductor device according to claim 1, wherein
the conductive substance is TiN, TaN, graphene, HfN, or WN.

9. A semiconductor wafer used for the semiconductor device according to claim 1, the semiconductor wafer comprising:
the base wafer, the first semiconductor crystal layer, and the second semiconductor crystal layer, wherein
the first semiconductor crystal layer is positioned above the base wafer, and
the second semiconductor crystal layer is positioned above a part or all of the first semiconductor crystal layer.

10. The semiconductor wafer according to claim 9, further comprising:
a first separation layer that is positioned between the base wafer and the first semiconductor crystal layer, and electrically separates the base wafer from the first semiconductor crystal layer; and
a second separation layer that is positioned between the first semiconductor crystal layer and the second semiconductor crystal layer, and electrically separates the first semiconductor crystal layer from the second semiconductor crystal layer.

11. The semiconductor wafer according to claim 10, wherein
the first separation layer is made of an amorphous insulator.

12. The semiconductor wafer according to claim 10, wherein
the first separation layer is made of a semiconductor crystal having a wider band gap than a band gap of a semiconductor crystal constituting the first semiconductor crystal layer.

13. The semiconductor wafer according to claim 9, further comprising:
a second separation layer that is positioned between the first semiconductor crystal layer and the second semiconductor crystal layer, and electrically separates the first semiconductor crystal layer from the second semiconductor crystal layer, wherein
the base wafer is in contact with the first semiconductor crystal layer on a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the first semiconductor crystal layer in the vicinity of the bonding plane.

14. The semiconductor wafer according to claim 10, wherein
the second separation layer is made of an amorphous insulator.

15. The semiconductor wafer according to claim 10, wherein
the second separation layer is made of a semiconductor crystal having a wider band gap than a band gap of a semiconductor crystal constituting the second semiconductor crystal layer.

16. The semiconductor wafer according to claim 9, comprising:
a plurality of the second semiconductor crystal layers, wherein
the plurality of second semiconductor crystal layers are respectively arranged regularly within a plane parallel to an upper plane of the base wafer.

17. A method for producing the semiconductor wafer according to claim 9, the method comprising:
first semiconductor crystal layer forming of forming the first semiconductor crystal layer above the base wafer; and
second semiconductor crystal layer forming of forming the second semiconductor crystal layer above a partial area of the first semiconductor crystal layer, wherein
the second semiconductor crystal layer forming comprises:
epitaxial growth of forming the second semiconductor crystal layer on a semiconductor crystal layer forming wafer by epitaxial growth,
forming, on the first semiconductor crystal layer, on the second semiconductor crystal layer, or on both of the first semiconductor crystal layer and the second semiconductor crystal layer, a second separation layer that electrically separates the first semiconductor crystal layer from the second semiconductor crystal layer, and
bonding the base wafer including the first semiconductor crystal layer to the semiconductor crystal layer forming wafer so that the second separation layer positioned on the first semiconductor crystal layer will be bonded to the second semiconductor crystal layer, that the second separation layer positioned on the second semiconductor crystal layer will be bonded to the first semiconductor crystal layer, or that the second separation layer positioned on the first semiconductor crystal layer will be bonded to the second separation layer positioned on the second semiconductor crystal layer.

18. The method according to claim 17, for producing the semiconductor wafer, wherein
the first semiconductor crystal layer forming comprises:
epitaxial growth of forming the first semiconductor crystal layer on a semiconductor crystal layer forming wafer by epitaxial growth;
forming, on the base wafer, on the first semiconductor crystal layer, or on both of the base wafer and the first semiconductor crystal layer, a first separation layer that electrically separates the base wafer from the first semiconductor crystal layer; and
bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

19. The method according to claim 17, for producing the semiconductor wafer, wherein
the first semiconductor crystal layer is made of SiGe, and the second semiconductor crystal layer is made of a Group III-V compound semiconductor crystal,
the method comprises, prior to the first semiconductor crystal layer forming, forming a first separation layer made of an insulator on the base wafer, and
the first semiconductor crystal layer forming comprises:
forming a SiGe layer, which serves as a starting material of the first semiconductor crystal layer, on the first separation layer; and
enhancing the concentration of Ge atom in the SiGe layer by heating the SiGe layer in an oxidizing atmosphere to oxidize a surface.

20. The method according to claim 17, for producing the semiconductor wafer, wherein
the first semiconductor crystal layer is made of a Group IV semiconductor crystal, and the second semiconductor crystal layer is made of a Group III-V compound semiconductor crystal, the method comprising:
forming a first separation layer made of an insulator on a surface of a semiconductor layer material wafer made of a Group IV semiconductor crystal;
injecting, via the first separation layer, cations to a predetermined separation depth of the semiconductor layer material wafer;
boding the semiconductor layer material wafer to the base wafer, so that a surface of the first separation layer will be bonded to a surface of the base wafer;
changing the Group IV semiconductor crystal positioned at the predetermined separation depth by heating the semiconductor layer material wafer and the base wafer, and reacting the cations having been injected to the predetermined separation depth and Group IV atom constituting the semiconductor layer material wafer;
separating the semiconductor layer material wafer from the base wafer, thereby detaching, from the semiconductor layer material wafer, the Group IV semiconductor crystal positioned nearer to the base wafer than to the changed portion of the Group IV semiconductor crystal having been changed in the changing; and
polishing a crystal layer made of the Group IV semiconductor crystal remaining on the base wafer.

21. The method according to claim 17, for producing the semiconductor wafer, comprising, prior to the first semiconductor crystal layer forming, forming, on the base wafer, a first separation layer made of a semiconductor crystal having a wider band gap than a band gap of a semiconductor crystal constituting the first semiconductor crystal layer by epitaxial growth, wherein
the first semiconductor crystal layer forming is forming the first semiconductor crystal layer on the first separation layer by epitaxial growth.

22. The method according to claim 17, for producing the semiconductor wafer, wherein
the first semiconductor crystal layer forming is forming the first semiconductor crystal layer on the base wafer by epitaxial growth.

23. The method according to claim 22, for producing the semiconductor wafer, wherein
impurity atoms exhibiting a p-type or n-type conductivity type are contained in the vicinity of a surface of the base wafer, and
in the forming of the first semiconductor crystal layer by epitaxial growth, the first semiconductor crystal layer is doped with impurity atoms exhibiting a conductivity type different from a conductivity type of impurity atoms contained in the base wafer.

24. A method for producing the semiconductor wafer according to claim 15, comprising:
second semiconductor crystal layer forming of forming the second semiconductor crystal layer on a semiconductor crystal layer forming wafer by epitaxial growth;
second separation layer forming of forming, on the second semiconductor crystal layer, a second separation layer made of a semiconductor crystal having a wider band gap than a band gap of a semiconductor crystal constituting the second semiconductor crystal layer by epitaxial growth;
first semiconductor crystal layer forming of forming the first semiconductor crystal layer on the second separation layer by epitaxial growth;
forming, on the base wafer, on the first semiconductor crystal layer, or on both of the base wafer and the first semiconductor crystal layer, a first separation layer that electrically separates the base wafer from the first semiconductor crystal layer; and
bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

25. The method according to claim 17, for producing the semiconductor wafer, further comprising:
prior to forming a semiconductor crystal layer on the semiconductor crystal layer forming wafer, forming a crystalline sacrificial layer on a surface of the semiconductor crystal layer forming wafer by epitaxial growth; and
separating the semiconductor crystal layer forming wafer from the semiconductor crystal layer having been formed by epitaxial growth on the semiconductor crystal layer forming wafer, by removing the crystalline sacrificial layer, after bonding the base wafer to the semiconductor crystal layer forming wafer.

26. The method according to claim 17, for producing the semiconductor wafer, comprising:
any one of patterning the second semiconductor crystal layers in a regular arrangement after having formed the second semiconductor crystal layers by epitaxial growth, or forming the second semiconductor crystal layers in a regular arrangement by selective epitaxial growth.

27. A method for producing a semiconductor device, the method comprising:
producing a semiconductor wafer comprising the first semiconductor crystal layer and the second semiconductor crystal layer by using the method according to claim 17 for producing the semiconductor wafer;
forming a conductive substance whose work function Φ_{M} satisfies at least one of relations respectively represented by (1) φ₁<Φ_{M}<φ₂+E_{g2}, and (2) |Φ_{M}−φ₁|≦0.1 eV and |(φ₂+E_{g2})−Φ_{M}|≦0.1 eV;
removing the conductive substance in a region in which a gate electrode is to be formed;
forming a gate insulating layer and a gate electrode in the region from which the conductive substance has been removed; and
patterning and heating the conductive substance thereby forming a first source and a first drain on both sides of the gate electrode positioned on the first semiconductor crystal and forming a second source and a second drain on both sides of the gate electrode positioned on the second semiconductor crystal,
where φ₁ represents an electron affinity of a crystal constituting a semiconductor crystal layer having a part thereof functioning as an N-type channel, which layer is selected from among the first semiconductor crystal layer and the second semiconductor crystal layer, and φ₂ and E_{g2} represent an electron affinity and a band gap of a crystal constituting a semiconductor crystal having a part thereof functioning as a P-type channel, which layer is selected from among the first semiconductor crystal layer and the second semiconductor crystal layer.
